(19) United States
(12) Patent Application Publication
(10) Pub. No.: US 2006/0267808 A1
(43) Pub. Date: Nov. 30, 2006

(54) Secure drive system enabled by matching media code

(75) Inventors: Jathan D. Edwards, Afton, MN (US); Roger C. Culhane, Stillwater, MN (US)

Correspondence Address: Attention: Eric D. Levinson;Imation Corp., Legal Affairs, P.O. Box 64898, St. Paul, MN, 55164-0898, US

(73) Assignee: Imation Corp.

(21) Appl. No.: 11/440,323

(22) Filed: May 23, 2006

Related U.S. Application Data
(60) Provisional application No. 60/707,060, filed on Aug. 10, 2005.
(60) Provisional application No. 60/684,325, filed on May 24, 2005.

(51) Int. Cl. H03M 7/00

(52) U.S. Cl. 341/50

(57) ABSTRACT

The invention is directed to coded optical media that allows a proprietary media handling system to enable particular drive features on an optical drive system. In particular, a coded optical medium comprises an otherwise standardized format optical medium that includes a particular set of preformatted manufacturer identification (MID) code values that can be read by the proprietary media handling system and compared with a set of internally preset code values. On the condition that the particular set of preformatted MID code values match the internally preset code values, the proprietary media handling system allows access to data stored on medium or, alternatively, enables special features. In this manner, the prerequisite code value match between the coded optical media and media handling system prevent non-certified media use in the optical drive system or, alternatively, enable specialized features only with optical media having accepted coding.

This application claims the benefit of U.S. Provisional Application No. 60/707,060 filed Aug. 10, 2005, and U.S. Provisional Application Ser. No. 60/684,325 filed May 24, 2005, the entire contents of which are incorporated herein by reference.

### TECHNICAL FIELD

The invention relates to data storage systems and, more particularly, to coded optical media storage systems.

### BACKGROUND

Optical media provide high capacity removable storage of digital data with a long life. Optical media store data in accordance with industry standard formats such as compact disc-recordable/rewritable (CD-R/RW), digital versatile disk recordable/rewritable (DVD +/− R/RW), high definition-digital versatile disk-recordable/rewritable (HD-DVD-R/RW), and Blue-Ray disc-recordable/rewritable (BD-R/RE). These standard formats have resulted in competitive pricing and volume production of both optical media and drive elements. In addition, these standard drive formats enable interchangeability or compatibility of optical media made by a number of manufacturers across a number of drive platforms. For example, a CD-R disc can be read on almost any CD-ROM drive, CD-R or CD-R/RW recorder, MultiRead-compliant DVD-ROM drive or recorder, and most consumer electronics.

Recordable optical media often include some form of a manufacturer identification (MID) code that identifies the disc. The MID is read by a drive system when a disc is inserted to allow the drive to accommodate the particular disc. This MID code is preformatted at the mastering stage according to the media format standards and typically includes a number of information fields listing, for example, the manufacturer of the disc, the media format type, recording speed ranges, and write strategy settings suggested for the drive. More specifically, the MID code is typically recorded onto a master and then converted to the surface relief stamper that is used to injection mold the disks. Consequently, the MID code is formed in the data layer of optical media during the manufacture process. The standardized format for the MID code provides media information to the drive system to facilitate interchangeability between numerous media and drive suppliers.

### SUMMARY

In general, the invention is directed to coded optical media that allows a proprietary media handling system to enable particular drive features on an optical drive system. In particular, a coded optical medium comprises an otherwise standardized format optical medium that includes a particular set of preformatted manufacturer identification (MID) code values that can be read by the proprietary media handling system and compared with a set of internally preset code values. As used herein, MID code values refers to specific field values within the collective MID code listing as defined by a media specification document. On the condition that the particular set of preformatted MID code values match the internally preset code values, the proprietary media handling system allows access to data stored on the medium, allows a drive to write data to the medium, or enables special features. In this manner, the prerequisite code value match between the coded optical media and media handling system prevent non-certified media use in the optical drive system or, alternatively, enable specialized features only with optical media having accepted coding.

A coded optical medium may comprise an optical medium compatible with industry standard formats such as compact disc-recordable/rewritable (CD-R/RW), digital versatile disk recordable/rewritable (DVD +/− R/RW), high definition-digital versatile disk-recordable/rewritable (HD-DVD-R/RW), and Blue-Ray disc-recordable/rewritable (BD-R/RE) having a drive readable MID code that identifies the optical medium as meeting a preset criteria.

In general, the MID code is preformatted at the mastering stage and conforms to a standardized format comprising a plurality of fields that provide media information to the drive system to facilitate interchangeability between numerous media and drive suppliers. Specifically, a number of the fields contain MID code values prescribed by the media specification document and are not freely varied by the media manufacturer. For example, the DVD+R specification stipulates a number of fields within the MID code that are common to all media of the DVD+R format, e.g., disc category, disc size, and recording density. The DVD+R specification also includes a number of fields that are particular to a given media manufacturer and to the characteristics of the media they provide, e.g., disc manufacturer ID, basic write strategy parameters, and the like. Additionally, the DVD+R specification includes non-particular fields that are authorized by the format specification or assigned at the discretion of the media manufacturer, such as disc application code, media type ID, and Product Revision Number (PRN). Accordingly, the values contained in the non-particular fields do not affect drive identification of the media type, as specified in the common fields, or the ability of the drive to properly write a particular media, as specified in the particular fields. Other optical standards, such as Blu-ray and HD-DVD may define similar information, which is also referred to here as MID code values of an MID code.

As described herein, a coded optical medium comprises an otherwise standardized format optical medium that includes a particular set of preformatted MID code values that can be read by a proprietary media handling system and compared with a set of internally preset code values. In particular, the particular set of preformatted MID code values includes code values contained in a particular field and a non-particular field of the MID code, such as the disc manufacturer ID and the PRN, respectively. Since the PRN may be assigned by the media manufacturer, a media manufacturer may assign each coded optical medium a specific identification number in the PRN field. The specific identification number may be used to identify media as meeting a preset criteria such as a particular standard, quality, or having particular features. Consequently, a proprietary media handling system can ensure a prerequisite code match between the coded optical media and the media handling drive system by comparing preset code values, i.e., the disc manufacturer ID and the specific identification number, to the MID code values stored in the disc manufacturer ID field and the PRN field of the coded optical medium.

The specially encoded optical media bearing a reserved combination of particular and non-particular fields, such as a disc manufacturer ID and a PRN, may identify the optical medium as meeting a criteria, such as a particular standard or having particular features. For example, optical media used for archive optical applications are required to meet a standard quality or reliability. The specially encoded media may also provide added levels of security by requiring password verification prior to allowing access to the optical medium. As an example, the optical medium may enable multi-level coding, e.g., a machine readable indicia and human readable code printed on the disc. In any case, a proprietary media handling system may allow privileged access only to optical media meeting particular standards or having acceptable coding.

The proprietary media handling system may comprise recording drives, printing engines, autoloaders, jukeboxes, or other handling systems that load and unload optical media from the optical drive or printing tray. More specifically, the media handling system may include means for interrogating the particular set of fields within the MID code that identify the coded optical medium as meeting a preset criteria. For the multi-level coding options, the media handling system may include optical sensors or detection elements to read the indicia on the coded optical media. Consequently, the media handling system prevents the optical drive from processing non-certified media, or may allow special features, such as archive verification software features, only with certified media.

In one embodiment, the invention is directed to a method comprising receiving an optical medium including optically detectable features that store data and are readable by a drive system of a media handing system and a preformatted manufacturer identification (MID) code including optically detectable features that store a set of MID code values and are readable by the media handing system, wherein the set of MID code values comprise a first MID code value that is particular to a media manufacturer and a second MID code value that is assigned by the optical media manufacturer, comparing the set of MID code values to a set of preset MID code values that identify the optical medium as meeting a preset criteria and are stored in the media handing system, allowing access to the optical medium subject matching the set of MID code values and the set of preset code values, and limiting access to the optical medium subject to failing to match the set of MID code values and the set of preset code values.

In another embodiment, the invention is directed to a media handling system comprising one or more elements to receive an optical medium that includes optically detectable features that store data and are readable by a drive system, one or more optical elements to read a set of preformatted manufacturer identification (MID) code values that identify the optical medium as meeting a criteria, wherein the set of MID code values comprise a first MID code value that is particular to a media manufacturer and a second MID code value that is assigned by the optical media manufacturer, one or more elements to store a set of preset code values that identify optical media as meeting the criteria, and one or more elements to compare the set of MID code values to the set of preset code values, allow access to the optical medium subject to matching the set of MID code values and the set of preset code values, and limiting access to the optical medium subject to failing to match the set of MID code values and the set of preset code values.

In a further embodiment, the invention is directed to an optical medium comprising optical detectable features that store data and are readable by a drive system of a media handing system, and a set of preformatted manufacturer identification (MID) code values that identify the optical medium as meeting a criteria and is readable by the media handling system, wherein the set of preformatted MID code values comprise a first MID code value that is particular to the optical medium from a media manufacturer and a second MID code value that is assigned by a media manufacturer, and wherein access to the optical medium is allowed subject to matching the set of MID code values with a set of preset code values stored in a media handling system.

In another embodiment, the invention is directed to a system comprising a device that stores data and includes a set of features that identify the device as meeting a criteria, wherein the set of features include a first value that is assigned according to a specification format and a second value that is freely assigned by the device manufacturer, and an apparatus that reads the features on the device, stores a set of preset values that identify the device as meeting a preset criteria, and selectively enables access to the device subject to matching the set of features to the set of preset values.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a block diagram illustrating an exemplary embodiment of an optical drive system that allows privileged access to optical media subject to identifying the media as meeting a criteria.

FIG. 2 is a block diagram illustrating a media handling system suitable for use in the optical drive system that identifies the media as meeting a criteria in accordance with an embodiment of the invention.

FIG. 3 is a flow chart illustrating a method for identifying optical media as meeting a preset criteria in accordance with an embodiment of the invention.

### DETAILED DESCRIPTION

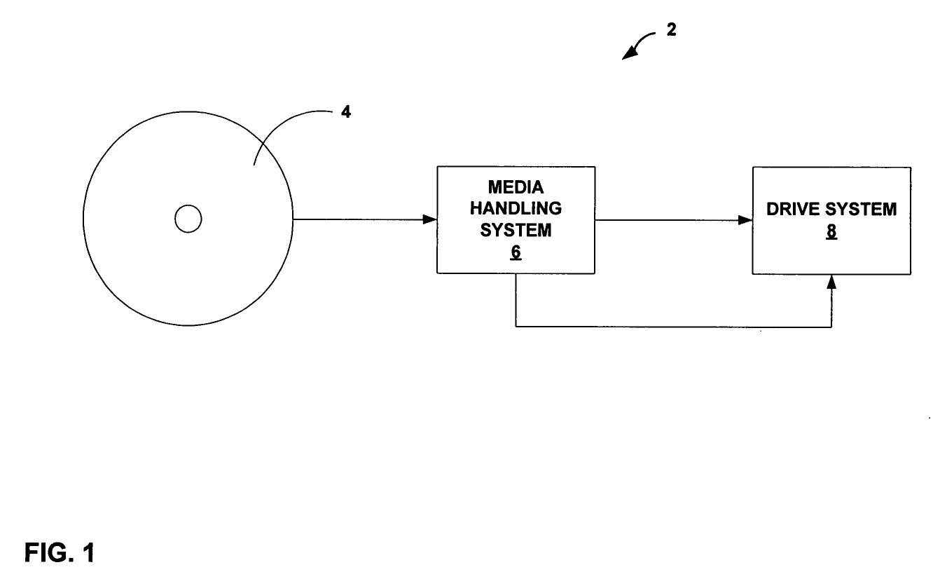

FIG. 1 is a block diagram illustrating an exemplary optical drive system 2 that allows privileged access to optical medium 4 or particular drive features on optical drive system 2. In general, optical drive system 2 includes media handling system 6 to load and unload, i.e., shuffle, optical medium 4 in and out of optical drive system 8 and allow privileged access to optical medium 4 subject to identifying optical media as meeting a preset criteria, and optical drive 8 to physically access optical medium 4. More specifically, media handling system 6 identifies optical medium 4 as meeting a preset criteria by comparing a particular set of MID code values with a set of internally preset code values. If the set of MID code values does not match the set of internally preset code values, media handling system 6 does not identify optical medium 4 as meeting the preset criteria, optical drive 8 may not access optical medium 4 or, alternatively, access only a limited subset of features. In contrast, if the set of MID code values and the set of internally preset code values both match preset criteria, e.g., such that a logical AND is satisfied in media handing system 6 with respect to both the MID code values and the set of internally preset code values, media handling system 6 identifies optical medium 4 as meeting the criteria, and optical drive 8 may access optical medium 4 or possibly enable specialized features, such as proprietary software features. In this manner, optical drive system 2 may prevent non-certified media from being accessed by optical drive 8, or prevent specialized features from being used with non-certified media.

The techniques described herein may be used specifically to limit a drive's ability to read data from a non-certified medium. In another example, the techniques described herein may be used to limit a drive's ability to write data to a non-certified medium. In yet another example, the techniques described herein may be used to enable special software features of the drive only for certified media.

As described herein, optical medium 4 may comprise optical media compatible with industry standard formats such as compact disc-recordable/rewritable (CD-R/RW), digital versatile disk recordable/rewritable (DVD +/− R/RW), high definition-digital versatile disk-recordable/rewritable (HD-DVD-R/RW), and Blue-Ray disc-recordable/rewritable (BD-R/RE) having a drive readable manufacturer identification (MID) code that identifies optical medium 4 as meeting a preset criteria. Generally, each of optical medium 4 have a drive readable MID code that is preformatted at the mastering stage and conforms to a standardized format comprising a plurality of fields that provide media information to optical drive 8 to facilitate interchangeability between numerous media and drive suppliers. The MID code includes various fields such as common fields that identify information common to all disks of a given format, particular fields that identify particular information for a given media from a given manufacturer, and non-particular fields that identify information authorized by the format licensors or assigned at the discretion of the media manufacturer.

For example, the DVD+R specification stipulates a number of fields within the MID code that are common to all media of this type such as disc size, recording density, and the like. In addition, the DVD+R specification includes a number of fields that are particular to a given media manufacturer and to the characteristics of the media they provide such as disc manufacturer ID, basic write strategy parameters, and the like. Furthermore, the DVD+R specification includes non-particular fields either authorized by the format or assigned at the discretion of the media manufacturer such as disc application code, media type ID, product revision number (PRN), and the like.

The values for the non-particular fields do not affect drive identification of the media type, as specified in common fields, or in the drive's ability to properly write a particular media, as specified in particular fields. Thus, the media manufacturer can assign a specific identification number in the PRN field to identify optical medium 4 as meeting a preset criteria such as a particular standard, quality, or reliability. For example, the media manufacturer may assign a specific identification number in the PRN field of the MID code to identify special uses related to secured archive applications. However, the PRN field, and non-particular fields in general, do not provide a secure code.

As a result, media handling system 6 interrogates a set of MID code values including a MID particular field, e.g., disc manufacturer identification field, and a non-particular field, e.g., PRN field, to ensure a unique prerequisite match between optical medium 4 and media handling system 6. In other words, upon the condition that both fields, i.e., the disc manufacturer identification field and the PRN field, match the prerequisite code values stored in media handling system 6, optical drive 8 may access optical medium 4 or access special features which are not available if optical media does not meet the criteria. The special features may include, for example, archive verification software in the case archive optical applications. However, if the set of MID code values do not match the internally preset code values, media handling system 6 prohibits optical drive 8 from accessing optical medium 4. The set of MID code values do not match the internally preset code values if the first and second code values of the set of MID code values do not match the preset code values individually or together. In this manner, the prerequisite match code match between a set of MID code values and internally preset code values prevent non-certified media use in optical drive 8 or, alternatively, enable specialized features only with optical media having acceptable coding.

Specially coded optical medium 4 may also provide added levels of security by requiring password verification prior to allowing access to optical medium 4. As an example, optical medium 4 may enable multi-level coding, e.g., a machine readable indicia or human readable code printed on the disc. Consequently, the machine readable indicia, particularly in conjunction with the MID code, may provide multi-level coding and added levels of security.

Media handling system 6 may comprise a proprietary media handling system such as recording drives, printing engines, autoloaders, jukeboxes, or other handling systems that shuffle media in and out of optical drive 8. More specifically, media handling system 6 includes one or more elements (not shown) to shuffle optical medium 4 in and out of optical drive 8, optical sensors or detection elements (not shown) to read the MID code values on optical medium 4, memory to store preset code values that identify media as meeting a preset criteria, and a processor that allows access to optical medium 4 subject to matching the MID code values on optical medium 4 with the internally preset code values. By storing a reserved combination of particular and non-particular field values, such as the disc manufacturing identification value and a specific identification number, media handling system 6 can ensure a unique prerequisite code match between optical medium 4 and media handling system 6.

Optical drive 8 may comprise a single drive station or a plurality of drive stations. Optical drive 8 receives optical medium 4 from media handling system 6 via a slot, aperture, or transport mechanism, such as an automated tray or arm. Upon receiving optical medium 4, optical drive 8 positions the received optical medium 4 onto a spindle of the drive station. The drive station may include a drive head with a lens to focus light onto a surface of the data side of optical medium 4 in order to read data from or write data back to optical medium 4.

In some embodiments, optical drive system 2 forms an automated optical media library system associated with a computing device (not shown). In this case, media handling system 6 allows privileged access to optical medium 4 subject to matching a set of MID code values on optical medium 4 with internally preset code values and shuffles optical media in and out of optical drive 8 accordingly.

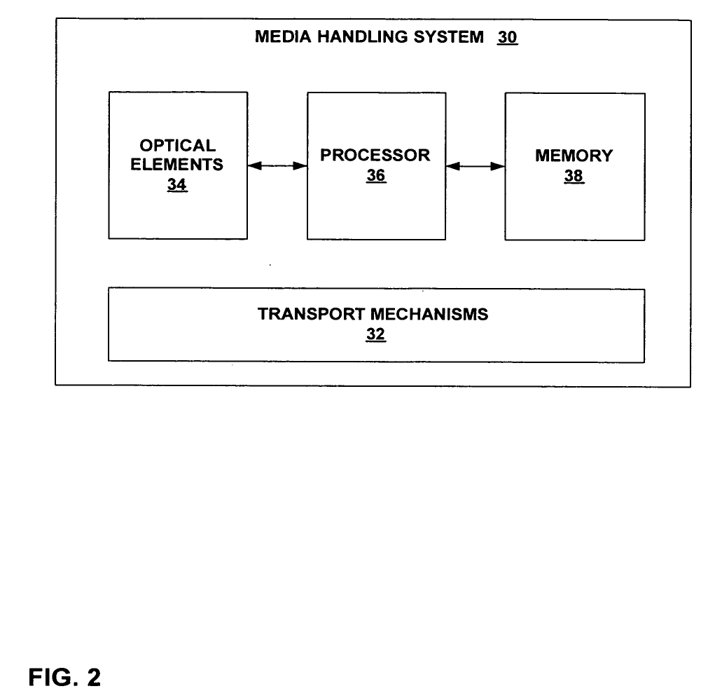

FIG. 2 is a block diagram illustrating media handling system 30 that allows privileged access to specially coded optical media, such as optical medium 4, subject to identifying the media as meeting a preset criteria. Media handling system 30 may comprise a proprietary media handling system such as recording drives, printing engines, autoloaders, jukeboxes, or other handling systems that shuffle media in and out of an optical drive or printing tray. In some embodiments, media handling system 30 may form part of an automated optical media library system associated with a computing device (not shown). In this case, media handling system 30 shuffles optical media in and out of an optical drive (not shown) and allows privileged access to the optical media subject to identifying the optical media as meeting particular criteria.

In the illustrated embodiment, media handling system 30 includes a transport mechanism 32 to shuffle optical media in and out of an optical drive, optical elements 34 to read the MID code on the optical media, memory 38 to store a set of preset code values that identify optical media as meeting a preset criteria, and a processor 36 to allow access to data stored on optical media subject to matching a particular set of MID code values of the MID code with the set of preset code values stored in memory 38. Transport mechanism 32 may include one or more elements which receive optical media that include a MID code as previously described. More specifically, transport mechanism may transport optical media between a storage case or location that may be internal or external to media handling system 32 and an optical drive. As an example, the storage case may comprise a multi-disc cartridge useful for autoloader or jukebox applications. As a procedural example, in order to load optical media into an optical drive, transport mechanism 32 may retrieve an optical medium from a stack of optical media on a spindle and position the medium on a drive tray. Transport mechanism 32 may unload an optical medium from the optical drive by removing the medium from the tray and position the medium on the appropriate spindle.

Memory 38 stores a set of internally preset code values that identify optical media as meeting a preset criteria, such as meeting particular quality or reliability standards for archive optical applications. The internally preset code values match the particular set of MID code values on specially coded optical media. Thus, the prerequisite code match between the coded optical media and media handling system prevent non-certified media use in the optical drive or, alternatively, enable specialized features only with optical media having accepted coding, i.e., the particular set of MID code values as previously described.

Optical elements 34 may read optically detectable features that store data and the MID code on the optical medium when the medium is positioned on the drive tray. More specifically, optical elements 34 initially read the particular set of MID code values when the disc first enters the drive, i.e., the disc manufacturer identification field and the PRN field.

Optical elements 34 output a signal to processor 36 based on the information received from the particular set of MID code values on the optical media. Processor 36 processes the signal received from optical elements 34 and allows privileged access to data stored on the media or enables special features, such as archive verification software in archive optical applications, if the output signal identifies the media as meeting particular criteria. More specifically, processor 36 compares the MID code values read from the optical media with the set of preset code values stored in memory 38. When the MID code values read from the optical media match the preset code values stored in memory 38, processor 36 identifies the optical media as meeting preset criteria, such as a particular quality or reliability standard and allows access to the data stored on the optical media. In contrast, when the comparison of the MID code values read from the optical media and the preset code values stored in memory 38 does not result in a match, processor 36 does not identify the media as meeting preset criteria and may allow access to only a limited subset of features or prohibit access to the media altogether. In particular, processor 36 may be communicatively coupled to an optical drive and output a corresponding signal to prohibit or allow access to the media.

Processor 36 may comprise a microprocessor, a digital signal processor (DSP), application specific integrated circuits (ASICs), field-programmable gate arrays (FPGAs), or other equivalent logic circuitry. Processor 36 may also comprise a general purpose processor that executes software instructions to perform the techniques described herein.

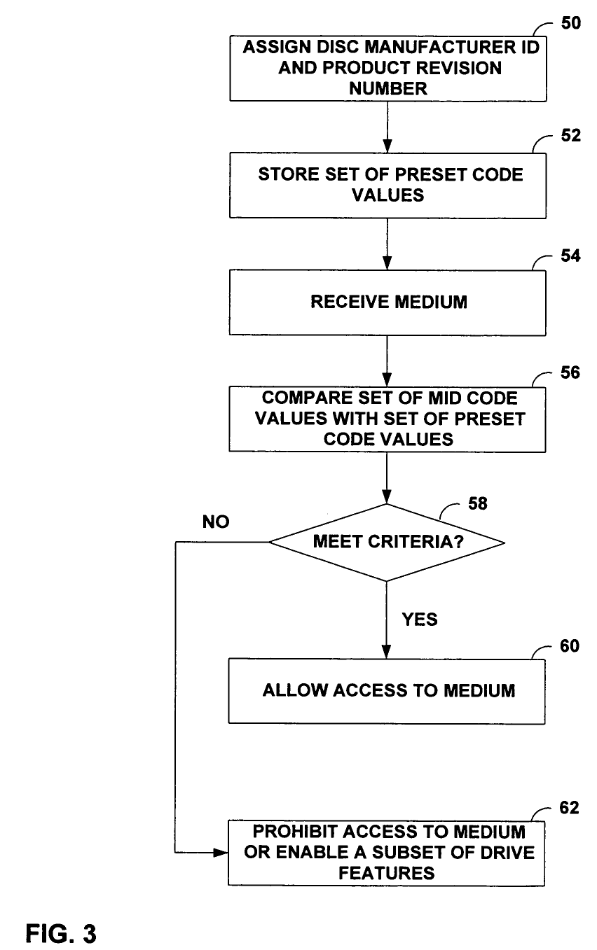

FIG. 3 is a flow chart illustrating a method for allowing privileged access to optical medium 4 in accordance with an embodiment of the invention. Initially, a media manufacturer records the MID code including the particular set of MID code values onto the optical medium (50). More specifically, the MID code is preformatted at the mastering stage according to the media format standards to provide information to the drive system in order to facilitate interchangeability between numerous media and drive suppliers. A number of the fields of the MID code are specified by the media specification document and are not freely varied by the media manufacturer. Other fields, such as the disk application field may be granted upon petition to the format licensee. However, the particular set of MID code values included in the specially coded optical media described within this example include a first MID code value that is particular to a media manufacturer and a second MID code value that is freely assigned by the media manufacturer. As an example, the first MID code value may comprise a disc manufacturer identification number. The second MID code value may comprise a PRN number that can be freely assigned by the media manufacturer to identify the optical media as meeting a preset criteria, such as meeting particular quality or reliability standards for archive optical applications. However, the second MID code value may not be unique and, therefore, is not sufficient to identify the optical media as meeting a preset criteria. Thus, the first and second MID code values are grouped to form a particular set in which the first and second code values are logically linked to each other to define a unique identifier.

Accordingly, media handling system 6 stores a set of internally preset code values (52) that identify media as meeting the preset criteria. The set of internally preset code values match the first and second MID values stored in the particular set of MID code values preformatted into specially coded optical medium 4.

Thus, when the media handling system 6 receives optical medium (54), the media handling system compares the set of MID code values with the set of internally preset code values (56). More specifically, the media handling system interrogates the particular set of MID code fields, e.g., disc manufacturer identification field and PRN field, containing the first and second MID code values and compares the values with the set of preset code values to determine if the optical media meets the criteria (58). When the set of MID code values read from the optical medium match the preset code values stored in media handling system 8, media handling system 6 identifies the optical media as meeting the preset criteria, such as meeting particular quality or reliability standards for archive optical applications, and allows access to the optical medium (60). In this case, media handling system may allow access to data stored on the optical medium, or may allow the drive to write data to the optical medium, or may enable special features, such as archive verification software. However, when the set of MID code values read from the optical media fail to match the preset code values stored in media handling system 6, media handling system 6 does not identify optical medium 4 as meeting the criteria and prohibits access to medium 4 altogether or, alternatively, enables a limited subset of drive features (62). In this manner, access to medium 4 can be either limited or prohibited altogether if the criteria is not met, as defined by the MID code values.

Various embodiments of the invention have been described. The techniques may be used to ensure that only authorized media is used by a handling system, thereby providing a level of quality assurance. In many of the examples above, the invention has been described as limiting access to data stored on a medium if the medium does not include the correct codes. As described, however, the same techniques may also be used to limit a drive's ability to write data to a medium, or to disable special or proprietary drive features if the medium does not include the correct codes. As other examples, limiting access may comprise one or more of allowing access to only a subset of features on the optical medium, denying access to the drive system, and denying access to a print engine.

Moreover, various modifications or additions may be made to the described embodiments without departing from the scope of the claimed invention. For example, while the invention is generally described for use in an optical drive system, the invention could be used in any system that identifies attributes or characteristics of an object by reading a code from the object that includes at least one number particular to a manufacturer and a number that can be freely assigned by the manufacturer. Any media having these characteristics, including magnetic disks, magnetic tapes, holographic media, magneto-optic media, or any other media format could take advantage of the techniques described herein. These and other embodiments are within the scope of the following claims.

1. A method comprising:
receiving an optical medium including optically detectable features that store data and are readable by a drive system and a preformatted manufacturer identification (MID) code including optically detectable features that store a set of MID code values and are readable by a media handling system, wherein the set of MID code values comprise a first MID code value that is particular to a media manufacturer and a second MID code value that is assigned by the optical media manufacturer;
comparing the set of MID code values to a set of preset MID code values that identify the optical medium as meeting a preset criteria and are stored in the media handling system;
allowing access to the optical medium subject matching the set of MID code values and the set of preset code values; and
limiting access to the optical medium subject to failing to match the set of MID code values and the set of preset code values.

2. The method of claim 1, wherein allowing access to the optical medium comprises one or more of allowing access to data stored on the optical medium, allowing the drive system to write data to the optical medium and allowing printing to the optical medium.

3. The method of claim 1, wherein the first MID code value comprises a disc manufacturer identification number and the second MID code value comprises a specific identification number.

4. The method of claim 1, wherein the first MID code value is stored in a format assigned MID field particular to the optical media manufacturer and the second MID code value is stored in an open MID field.

5. The method of claim 4, wherein the open MID field comprises a product revision number (PRN) field.

6. The method of claim 1, wherein comparing the set of MID code values to the set of preset MID code values comprises:
interrogating the first and second MID code values of the optical medium; and
comparing the first and second MID code values of the optical medium to the set of preset code values stored in the media handling system.

7. The method of claim 1, wherein matching the set of MID code values of the optical medium and the set of preset code values stored in the media handling system comprises identifying the optical medium as meeting the preset criteria.

8. The method of claim 1, wherein the set of MID code values identify the optical medium as meeting a manufacturer associated criteria.

9. The method of claim 1, further comprising at least one of machine readable indicia and human readable code printed on the optical medium that include information for allowing secure access to the optical medium.

10. The method of claim 1, wherein the optical medium comprises one of a compact disk read only memory (CD-ROM), a recordable compact disc (CD-R), a rewritable compact disk (CD-RW), a digital video disc read only memory (DVD-ROM), a DVD-R, a DVD-RW, a DVD+R, a DVD+RW, a high definition DVD-R, a HD-DVD-RW, a Blu-ray disc read only memory (BD-ROM), a BD-R, a BD-RE, and other such interchangeable standard format compact disc media.

11. The method of claim 1, wherein limiting access comprises one or more of allowing access to only a subset of features of the drive system, denying access to the drive system, denying access to a print engine, and denying any access to the optical medium by the drive system.

12. The method of claim 1, wherein the optical medium is included within a multi-disc cartridge.

13. A media handling system comprising:
one or more elements that receive an optical medium that includes optically detectable features that store data and are readable by a drive system;
one or more optical elements that read a set of preformatted manufacturer identification (MID) code values that identify the optical medium as meeting a criteria, wherein the set of MID code values comprise a first MID code value that is particular to a media manufacturer and a second MID code value that is assigned by the optical media manufacturer;
one or more elements that store a set of preset code values that identify optical media as meeting the criteria; and
one or more elements that compare the set of MID code values to the set of preset code values, allow access to the optical medium subject to matching the set of MID code values and the set of preset code values, and limit access to the optical medium subject to failing to match the set of MID code values and the set of preset code values.

14. The system of claim 13, wherein the first MID code value comprises a disc manufacturer identification number and the second MID code value comprises a specific identification number.

15. The system of claim 13, wherein the first MID code value is stored in a format assigned MID field particular to the optical media manufacturer and the second MID code value is stored in an open MID field.

16. The system of claim 15, wherein the open MID field comprises a product revision number (PRN) field.

17. The system of claim 13, wherein the one or more elements that compare the set of MID code values to the set of preset code values:
match the set of MID code values and the set of preset code values by interrogating the first and second MID code values of the set of MID code values and comparing the first and second MID code values with the set of preset code values.

18. The system of claim 13, wherein the one or more elements that compare the set of MID code values to the set of preset code values:
match the set of MID code values of the optical medium and the set of preset code values to identify the optical medium as meeting the preset criteria.

19. The system of claim 13, wherein the set of MID code values identify the optical medium as meeting a manufacturer associated criteria.

20. The system of claim 13, further comprising one or more elements to read at least one of machine readable indicia and human readable code printed on the optical medium that include information for allowing secure access to the optical medium.

21. The system of claim 13, wherein the optical medium comprises one of a compact disk read only memory (CD-ROM), a recordable compact disc (CD-R), a rewritable compact disk (CD-RW), a digital video disc read only memory (DVD-ROM), a DVD-R, a DVD-RW, a DVD+R, a DVD+RW, a high definition DVD-R, a HD-DVD-RW, a Blu-ray disc read only memory (BD-ROM), a BD-R, a BD-RE, and other such interchangeable standard format compact disc media.

22. The system of claim 13, wherein the system limits access by one or more of the following: allowing access to only a subset of features on the optical medium, denying access to the drive system, and denying access to a print engine.

23. The system of claim 13, wherein the optical medium is included within a multi-disc cartridge.

24. An optical medium comprising:
optical detectable features that store data and are readable by a drive system; and
a set of preformatted manufacturer identification (MID) code values that identify the optical medium as meeting a criteria and is readable by a media handling system,
wherein the set of preformatted MID code values comprise a first MID code value that is particular to the optical medium from a media manufacturer and a second MID code value that is assigned by a media manufacturer, and
wherein access to the optical medium is allowed subject to matching the set of MID code values with a set of preset code values stored in a media handling system.

25. A system comprising:
a device that stores data and includes a set of features that identify the device as meeting a criteria, wherein the set of features include a first value that is assigned according to a specification format and a second value that is freely assigned by a manufacturer of the device; and
an apparatus that reads the set of features on the device, compares the set of features against a set of preset values that identify the device as meeting a preset criteria, and selectively enables access to the device subject to matching the set of features to the set of preset values.

26. A method comprising:
receiving an optical medium including optically detectable features that store data and are readable by a drive system of a media handing system and a preformatted manufacturer identification (MID) code including optically detectable features that store a set of MID code values and are readable by the media handing system, wherein the set of MID code values comprise a first MID code value that is particular to a media manufacturer and a second MID code value that is assigned by the optical media manufacturer;
comparing the set of MID code values to a set of preset MID code values that identify the optical medium as meeting a preset criteria and are stored in the media handling system;
allowing access to specific features of a drive subject matching the set of MID code values and the set of preset code values; and
limiting access to the specific features of the drive subject to failing to match the set of MID code values and the set of preset code values.

27. A method comprising:
receiving a medium including a preformatted manufacturer identification (MID) code including a set of MID code values that comprise a first MID code value and a second MID code value;
comparing the set of MID code values to a set of preset MID code values that identify the medium as meeting a preset criteria;
allowing access to the medium upon matching the set of MID code values and the set of preset MID code values; and
limiting access to the medium upon failing to match the set of MID code values and the set of preset MID code values.
